(19) United States
(12) Patent Application Publication
(10) Pub. No.: US 2012/0299060 A1
(43) Pub. Date: Nov. 29, 2012

(54) NITRIDE SEMICONDUCTOR DEVICE AND MANUFACTURING METHOD THEREOF

(75) Inventors: Shinichi KOHDA, Kyoto (JP); Jun Shimizu, Toyama (JP)

(73) Assignee: Panasonic Corporation, Osaka (JP)

(21) Appl. No.: 13/569,847

(22) Filed: Aug. 8, 2012

Related U.S. Application Data
(63) Continuation of application No. PCT/JP2010/005792, filed on Sep. 27, 2010.

(30) Foreign Application Priority Data
Feb. 15, 2010 (JP) 2010-030128

(51) Int. Cl. H01L 29/38; H01L 21/20

(52) U.S. Cl. 257/190; 438/478; 257/E29.105; 257/E21.09

(57) ABSTRACT

A nitride semiconductor device includes: a silicon substrate; a buffer layer formed on the silicon substrate and comprised of a nitride semiconductor; and an active layer formed on the buffer layer and comprised of a nitride semiconductor. The buffer layer includes a first layer formed in contact with the silicon substrate, and a second layer formed in contact with the first layer and the active layer. The carbon concentration at an interface between the first layer and the second layer is in the range of 1×10¹⁹ atoms/cm³ to 1×10²¹ atoms/cm³, both inclusive. The first layer has the highest carbon concentration in a portion in contact with the silicon substrate. The second layer has the highest carbon concentration in a portion in contact with the first layer, and has the lowest carbon concentration in a portion in contact with the active layer.

### CROSS-REFERENCE TO RELATED APPLICATION

This is a continuation of PCT International Application PCT/JP2010/005792 filed on Sep. 27, 2010, which claims priority to Japanese Patent Application No. 2010-030128 filed on Feb. 15, 2010. The disclosures of these applications including the specifications, the drawings, and the claims are hereby incorporated by reference in their entirety.

### BACKGROUND

The present disclosure relates to nitride semiconductor devices and manufacturing methods thereof, and more particularly to nitride semiconductor devices formed on a silicon substrate and manufacturing methods thereof.

A nitride semiconductor is a wide bandgap semiconductor, and has a high breakdown electric field. The nitride semiconductor also has a higher saturated electron drift velocity than silicon semiconductors or compound semiconductors such as gallium arsenide (GaAs). Moreover, charges are generated at a hetero interface of aluminum gallium nitride (AlGaN) and gallium nitride (GaN) having a (0001) plane as a principal surface, etc. due to spontaneous polarization and piezoelectric polarization. The sheet carrier concentration at the hetero interface is 1×10¹³ cm⁻² or more even if an undoped material is used. Accordingly, a hetero junction field effect transistor (HFET) having a high current density can be implemented using a two-dimensional electron (2DEG) gas at the hetero interface. Thus, power transistors and high frequency transistors using nitride semiconductors have been actively researched and developed.

Substrates having a large lattice mismatch with a nitride semiconductor, such as sapphire, silicon carbide, or silicon substrates, are used as substrates for crystal growth of the nitride semiconductor. This is because a nitride semiconductor substrate is formed on a different kind of substrate by a vapor deposition method, and thus at present the cost is high and nitride semiconductor semiconductors having a large diameter cannot be produced. Silicon substrates having a large diameter have been mass-produced, and are advantageous in terms of the cost as well. However, the silicon substrates have the following disadvantages in terms of growth of the nitride semiconductor.

The thermal expansion coefficient of the nitride semiconductor is larger than that of silicon, and the difference therebetween is large. The nitride semiconductor is typically grown at a temperature as high as about 1,000° C. The nitride semiconductor is likely to be subjected to tensile stress when the nitride semiconductor is formed on a silicon substrate at a high temperature and then the temperature is decreased to room temperature. Accordingly, the nitride semiconductor formed on the silicon substrate tends to have a high density of defects, or cracks. Moreover, when forming a nitride semiconductor containing gallium, the material of the nitride semiconductor tends to form a compound with silicon. This makes it difficult to grow a flat nitride semiconductor film on the silicon substrate.

The following problems are also caused when forming a high frequency nitride semiconductor device on a silicon substrate. In high frequency nitride semiconductor devices, minority carriers near the substrate surface adversely affect high frequency characteristics. In the case of forming a nitride semiconductor on a high resistance silicon substrate, a parasitic channel layer is formed on the surface of the silicon substrate. This causes transmission loss, making the high frequency operation difficult. In order to suppress formation of the parasitic channel layer, it is necessary to increase the sheet resistance near the hetero interface between the high resistance silicon substrate and the nitride semiconductor.

In order to reduce such problems of the silicon substrates, it has been proposed to provide various buffer layers between the silicon substrate and the active layer. For example, it has been proposed to form an aluminum oxide layer on a silicon substrate by a sputtering method, and then form an aluminum nitride layer thereon (see, e.g., Japanese Patent Publication No. 2009-038395). It has also been proposed to form a nitride semiconductor by nitriding silicon on a silicon substrate to form silicon nitride, and then forming aluminum nitride thereon (see, e.g., Japanese Translation of PCT International Application No. 2008-522447). It has also been proposed to grow a buffer layer, which is comprised of GaN having a high carbon concentration, on a silicon substrate at a low temperature (see, e.g., Japanese Patent Publication No. 2007-251144).

### SUMMARY

However, such conventional buffer layers have various problems. In order to form an active layer having high crystallinity on a buffer layer, the buffer layer is required to have high flatness and crystallinity. In the high frequency nitride semiconductor device, the sheet resistance of the buffer layer need be increased. Moreover, in terms of the cost, the buffer layer need be formed by a process that can be performed as easily as possible. In the conventional methods, it is difficult to obtain a buffer layer that satisfies these requirements.

The present disclosure was developed to solve the above problems, and it is an object of the present disclosure to implement a nitride semiconductor device formed on a silicon substrate and having excellent high frequency characteristics.

In order to achieve the above object, a nitride semiconductor device of the present disclosure is configured to include a buffer layer comprised of a film having an inclined carbon concentration (hereinafter referred to as the “inclined carbon concentration film).

Specifically, an example nitride semiconductor device includes: a silicon substrate; a buffer layer formed on the silicon substrate and comprised of a nitride semiconductor; and an active layer formed on the buffer layer and comprised of a nitride semiconductor, wherein the buffer layer includes a first layer formed in contact with the silicon substrate, and a second layer formed in contact with the first layer and the active layer, a carbon concentration at an interface between the first layer and the second layer is in a range of 1×10¹⁹ atoms/cm³ to 1×10²¹ atoms/cm³, both inclusive, the first layer has a highest carbon concentration in a portion in contact with the silicon substrate, and the second layer has a highest carbon concentration in a portion in contact with the first layer, and has a lowest carbon concentration in a portion in contact with the active layer.

In the example nitride semiconductor device, the carbon concentration at the interface between the first layer and the second layer is in the range of 1×10¹⁹ atoms/cm³ to 1×10²¹ atoms/cm³, both inclusive, the first layer has the highest carbon concentration in the portion in contact with the silicon substrate, and the second layer has the highest carbon concentration in the portion in contact with the first layer, and has the lowest carbon concentration in the portion in contact with the active layer. Thus, the resistance of the buffer layer can be increased while improving crystallinity thereof. This can reduce transmission loss of the semiconductor device, and can suppress production of defects and cracks, whereby a nitride semiconductor device having excellent high frequency characteristics can be easily implemented.

In the example nitride semiconductor device, each of the first layer and the second layer may contain a group III element, and a composition of the group III element in the first layer may be the same as that of the group III element in the second layer.

In the example nitride semiconductor device, the second layer may be thicker than the first layer.

In the example nitride semiconductor device, the first layer may have a thickness of 5 nm or more and less than 40 nm.

In the example nitride semiconductor device, a full width at half maximum of a rocking curve of a (0001) plane of the second layer may be 3,000 arc seconds or less.

In the example nitride semiconductor device, a maximum operating frequency may be 2.5 GHz or more, or 25 GHz or more.

A first method for manufacturing a nitride semiconductor device includes the steps of: (a) performing crystal growth of a first layer comprised of a nitride semiconductor on a silicon substrate; (b) performing crystal growth of a second layer comprised of a nitride semiconductor on the first layer; and (c) performing crystal growth of an active layer comprised of a nitride semiconductor on the second layer, wherein the crystal growth is performed at a lower temperature in the step (a) than in the step (b).

In the first method, the crystal growth of the first layer is performed at a lower temperature than that of the second layer. This can increase the carbon concentration in the first layer, whereby the overall sheet resistance of the buffer layer can be increased while improving the overall crystallinity of the buffer layer.

A second method for manufacturing a nitride semiconductor device includes the steps of: (a) performing crystal growth of a first layer comprised of a nitride semiconductor on a silicon substrate; (b) performing crystal growth of a second layer comprised of a nitride semiconductor on the first layer; and (c) performing crystal growth of an active layer comprised of a nitride semiconductor on the second layer, wherein a ratio of a group V element to a group III element contained in a source gas is lower in the step (a) than in the step (b).

In the second method, the crystal growth of the first layer is performed at a lower V-III ratio than that in the crystal growth of the second layer. This can increase the carbon concentration in the first layer, whereby the overall sheet resistance of the buffer layer can be increased while improving the overall crystallinity of the buffer layer.

A third method for manufacturing a nitride semiconductor device includes the steps of: (a) performing crystal growth of a first layer comprised of a nitride semiconductor on a silicon substrate; (b) performing crystal growth of a second layer comprised of a nitride semiconductor on the first layer; and (c) performing crystal growth of an active layer comprised of a nitride semiconductor on the second layer, wherein in the step (a), a carbon material containing carbon is added to a source gas.

In the third method, the carbon material is added when performing the crystal growth of the first layer. This can increase the carbon concentration in the first layer, whereby the overall sheet resistance of the buffer layer can be increased while improving the overall crystallinity of the buffer layer.

In the third method, the carbon material may be hydrocarbon, and may be carbon tetrabromide.

The semiconductor device and the manufacturing method thereof according to the present disclosure can implement a nitride semiconductor device formed on a silicon substrate and having excellent high frequency characteristics.

### BRIEF DESCRIPTION OF THE DRAWINGS

FIG. 1 is a cross-sectional view showing a nitride semiconductor device according to an embodiment.

FIG. 2 is a chart showing a measurement result of the carbon concentration in a buffer layer according to the embodiment.

FIG. 3 is a chart showing a measurement result of the carbon concentration in a conventional buffer layer.

FIG. 4 is a graph showing the relation between the thickness of a first layer and the sheet resistance and crystallinity of a buffer layer.

FIG. 5 is a graph showing the relation between the sheet resistance of an aluminum nitride film and the transmission loss.

FIG. 6 is a cross-sectional view showing a modification of the nitride semiconductor device according to the embodiment.

FIG. 7 is a cross-sectional view showing a modification of the nitride semiconductor device according to the embodiment.

FIG. 8 is a diagram showing a bandgap in a gate region having a control layer formed therein.

FIG. 9 is a diagram showing a bandgap in a portion having no control layer formed therein.

### DETAILED DESCRIPTION

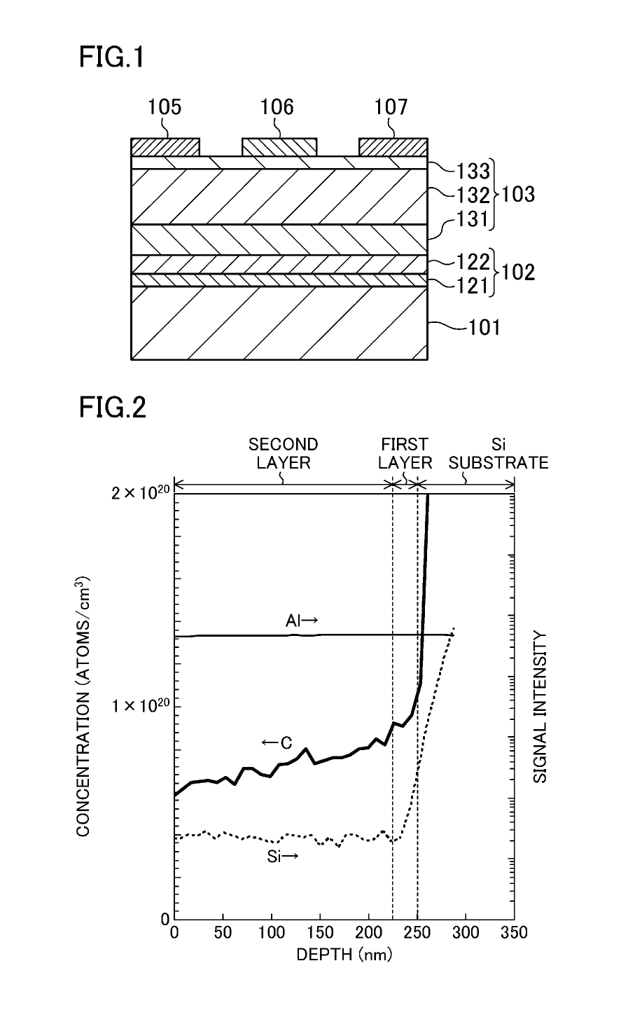

FIG. 1 shows a cross-sectional configuration of a nitride semiconductor device according to an embodiment. As shown in FIG. 1, the nitride semiconductor device of the present embodiment is a high electron mobility transistor (HEMT), and an active layer 103 is formed on a silicon (Si) substrate 101 having a high resistance, with a buffer layer 102 interposed therebetween. The buffer layer 102 has a first layer 121 formed in contact with the silicon substrate 101, and a second layer 122 formed in contact with the first layer 121 and the active layer 103. The active layer 103 has a buffer layer 131, an electron transit layer 132, and an electron supply layer 133, which are sequentially formed in this order from the bottom of the active layer 103. A source electrode 105, a gate electrode 106, and a drain electrode 107 are formed on the electron supply layer 133.

Each of the first layer 121 and the second layer 122 can be comprised of any compound represented by the general formula “AlₓGa₁₋ₓN” (where 0≦x≦33 1). The respective compounds of the first layer 121 and the second layer 122 may have the same or different compositions of a group III element. In the present embodiment, both the first layer 121 and the second layer 122 are comprised of aluminum nitride (AlN). The first layer 121 and the second layer 122 contain carbon, and the first layer 121 has a higher carbon concentration than the second layer 122. The carbon concentration in the second layer 121 is the highest at the interface with the first layer 121, and gradually decreases toward the interface with the active layer 103.

FIG. 2 shows the measurement result of the atomic concentration in a buffer layer formed by stacking a first layer with a thickness of 20 nm and a second layer with a thickness of 230 nm on a silicon substrate. The measurement was carried out by using a secondary ion mass spectrometer (SIMS). Each of the first layer and the second layer was an AlN film and was formed by a metal organic chemical vapor deposition (MOCVD) method. Trimethyl aluminum (TMA) was used as an aluminum (group III) material, and ammonia was used as a nitrogen (group V) material. The first layer was formed at a temperature of 900° C., and the second layer was formed at a temperature of 1,100° C.

As shown in FIG. 2, the carbon concentration is the highest at the interface between the first layer and the silicon substrate, which is about 1×10²⁰ atoms/cm³. This seems to be because the first layer is formed at a relatively low temperature, and thus carbon is introduced from TMA as a supply source of Al atoms into the first layer. However, the carbon concentration is as high as about 8×10¹⁹ atoms/cm³ even at a depth of about 230 nm corresponding to the interface between the first layer and the second layer. This seems to be because carbon atoms already staying in a crystal growth furnace are introduced into the film even when the second layer is formed at a relatively high temperature. The carbon concentration gradually decreases toward the upper surface of the second layer (toward the interface with the active layer), and is about 6×10¹⁹ atoms/cm³ near the surface of the second layer. Thus, a buffer layer comprised of an inclined carbon concentration film having an inclined carbon concentration is obtained by forming at a relatively low temperature a first layer having a high carbon concentration and then forming at a high temperature a second layer having a lower carbon concentration than the first layer. In FIG. 2, the carbon concentration has no distinct boundary between the first and second layers, and is continuously inclined. However, the carbon concentration may have a boundary between the first and second layers depending on the conditions under which the film is formed.

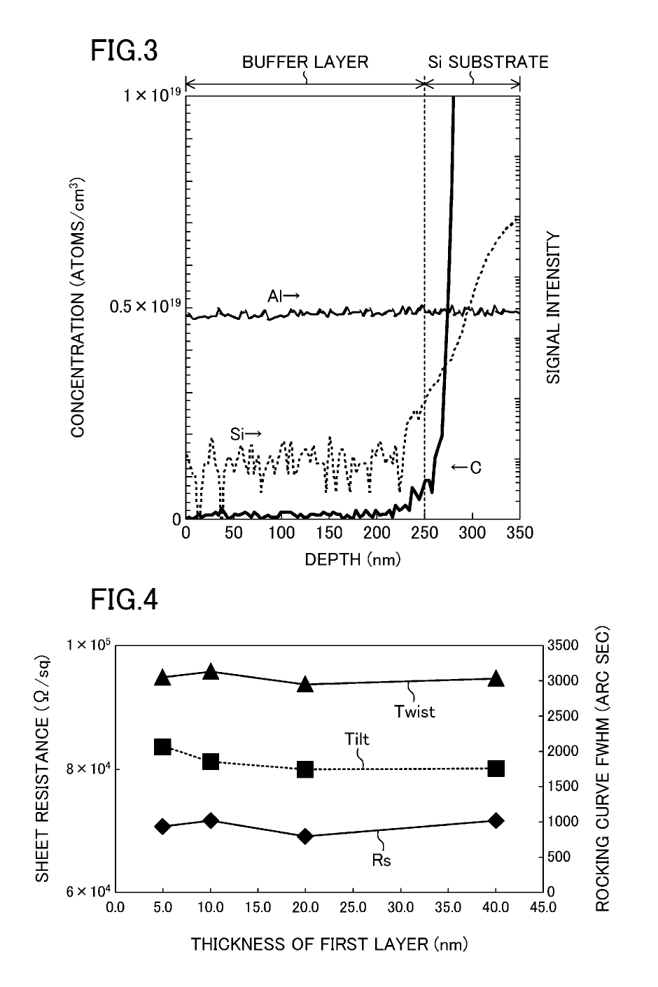

FIG. 3 shows the SIMS measurement result obtained in the case where a buffer layer comprised of AlN and having a thickness of 250 nm was formed on a silicon substrate at 1,100° C. The carbon concentration in the buffer layer is about 1×10¹⁷ atoms/cm³ or less, and the carbon concentration is almost constant in the buffer layer.

Table 1 shows the evaluation result of sheet resistance and crystallinity of a buffer layers having an inclined carbon concentration and a buffer layer having a constant carbon concentration. In Table 1, the “inclined carbon concentration film” is a stacked film of an AlN film formed with a thickness of 20 nm at 900° C. and an AlN film formed with a thickness of 100 nm at 1,100° C. The “high carbon concentration film” is an AlN film formed with a thickness of 120 nm at 900° C. The “low carbon concentration film” is an AlN film formed with a thickness of 120 nm at 1,100° C. The crystallinity was evaluated based on a full width at half maximum (FWHM) of a twist component ((10-11) diffraction) in an X-ray rocking curve of a (0001) plane.

TABLE 1

| | Low Carbon | High Carbon | Inclined Carbon |
|---|---|---|---|
| | Concen- | Concen- | Concen- |
| | tration Film | tration Film | tration Film |
| Sheet Resistance (kΩ/sq) | 1 | 78 | 69 |
| Crystallinity (arc sec) | 2,670 | 4,630 | 2,950 |

As shown in Table 1, the sheet resistance of the low carbon concentration film is as low as about 1 kΩ/cm², whereas the sheet resistance of the high carbon concentration film is as high as about 78 kΩ/cm². The sheet resistance of the inclined carbon concentration film is lower than that of the high carbon concentration film, but has a relatively high value of about 69 kΩ/cm². The low carbon concentration film has satisfactory crystallinity as FWHM of the twist component is about 2,670 arc seconds. The high carbon concentration film has reduced crystallinity as FWHM is about 4,630 arc seconds. The inclined carbon concentration film has satisfactory crystallinity as FWHM is about 2,950 arc seconds. Thus, a buffer layer having high resistance and high crystallinity is obtained by using an inclined carbon concentration film formed by stacking a first layer having a high carbon concentration and a second layer having a low carbon concentration.

FIG. 4 shows the relation between the thickness of a first layer having a high carbon concentration and the average sheet resistance and crystallinity in a plane of a buffer layer. The sheet resistance (Rs) of the buffer layer is almost constant when the thickness of the first layer is in the range of 5 nm to 40 nm. In this thickness range, FWHM of a twist component ((10-11) diffraction) and FWHM of a tilt component ((0002) diffraction) in a rocking curve are also almost constant. However, cracks were developed when the thickness of the first layer was 40 nm. This means that increasing the thickness of the first layer having a high carbon concentration and low crystallinity tends to produce cracks when the temperature decreases after crystal growth. Accordingly, the thickness of the first layer is preferably less than 40 nm.

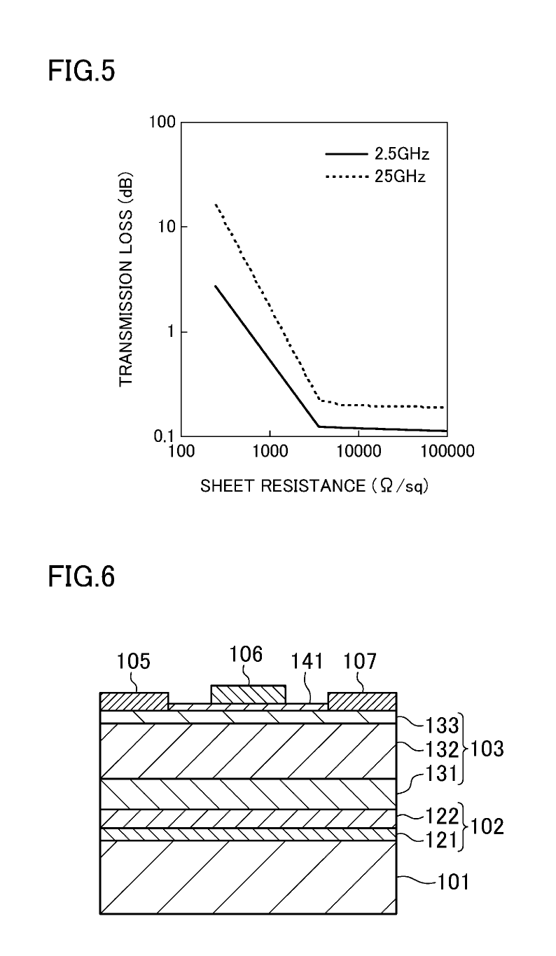

FIG. 5 shows the relation between the sheet resistance of a buffer layer and transmission loss at 2.5 GHz and 25 GHz. As shown in FIG. 5, at either frequency, increasing the sheet resistance of the buffer layer can reduce the transmission loss. Thus, a high performance semiconductor device having reduced transmission loss can be implemented by using as the buffer layer of the semiconductor device an inclined carbon concentration film formed by stacking a first layer having a high carbon concentration and a second layer having a low carbon concentration. Moreover, high crystallinity of the buffer layer can reduce defects in an active layer that is formed on the buffer layer, or can suppress production of cracks.

Although an example is shown in which the first layer having a high carbon concentration is formed at a relatively low temperature, the carbon concentration of the first layer may be increased by actively adding a carbon material as a carbon supply source in addition to normal group III and group V materials when forming the first layer. The carbon material may be a material containing no group III element and containing carbon. For example, a hydrocarbon gas such as methane, ethane, or propane may be used as the carbon material. Alternatively, carbon tetrabromide (CBr₄) may be used as the carbon material. In the case of adding the carbon material, the carbon concentration can be increased even if the first layer is formed at a relatively high temperature. Thus, the first layer may be formed at about 1,100° C. The first layer having a high carbon concentration may be formed by using a reduced ratio (V-III ratio) of the group V element to the group III element in the source gas.

The higher the carbon concentration of the first layer is, the higher the sheet resistance can be. However, if the first layer has an excessively high carbon concentration, the second layer also has a very high carbon concentration, which may reduce crystallinity of the buffer layer. On the other hand, if the first layer has an excessively low carbon concentration, the sheet resistance is reduced. Thus, it is preferable that the carbon concentration near the interface between the first and second layers be in the range of 1×10¹⁹ atoms/cm³ to 1×10²¹ atoms/cm³, both inclusive.

The buffer layer 131 can be a single-layer film having a thickness of about 500 nm and comprised of any compound represented by the general formula AlₓGa₁₋ₓN (where 0≦x≦1). The buffer layer 131 may be a superlattice film formed by alternately stacking AlₓGa₍₁₋ₓ₎N and Al_{y}Ga_{(1-y)}N (where 0≦x<y and x<y≦1). Alternatively, the buffer layer 131 may be a combined film of the single-layer film and the superlattice film. The buffer layer 131 can be provided as necessary. Providing the buffer layer 131 can reduce bending of the silicon substrate and can reduce the possibility of production of cracks in the nitride semiconductor layer. The thicker the buffer layer 131 is, the higher the crystallinity of the nitride semiconductor layer that is formed on the buffer layer 131 can be, and the higher the breakdown voltage of the semiconductor device can be. However, if the buffer layer 131 has an excessively large thickness, cracks tend to be produced.

The electron transit layer 132 may be comprised of, e.g., undoped GaN with a thickness of 2 μm. The term “undoped” herein means that no impurity has been introduced intentionally. It is more preferable that the electron transit layer 132 contain a smaller amount of impurities that trap carriers such as carbon atoms. In the case where the electron transit layer 132 is formed by an MOCVD method, the electron transit layer 132 can be formed at about 1,050° C.

The electron supply layer 133 can be comprised of any material that has a wider bandgap than the electron transit layer 132 and that can form a 2DEG layer near the interface of the electron transit layer 132 with the electron supply layer 133. For example, if the electron transit layer 132 is comprised of undoped GaN, a 2DEG layer can be formed due to spontaneous polarization and piezoelectric polarization by using the electron supply layer 133 comprised of undoped AlGaN with a thickness of 50 nm. If the electron supply layer 133 is formed by an MOCVD method, the electron supply layer 133 can be formed at about 1,100° C.

Each of the source electrode 105 and the drain electrode 107 need only form ohmic junction with the semiconductor layer that is in contact therewith, and may have, e.g., a stacked structure of titanium (Ti) and aluminum (Al). The gate electrode 106 need only form Schottky junction with the semiconductor layer that is in contact therewith, and may have, e.g., a stacked structure of nickel (Ni), platinum (Pt), and gold (Au). The source electrode 105, the drain electrode 107, and the gate electrode 106 may be formed by an electron beam (EB) deposition method, a lift-off method, etc.

When the source electrode 105 and the drain electrode 107 are operated, electrons travel at a high speed within a channel comprised of the 2DEG layer, and a drain current flows. By controlling the voltage of the gate electrode 106, a depletion layer located immediately below the gate electrode 106 can be controlled, and the drain current can be controlled.

Instead of the HEMT, the nitride semiconductor device of the present embodiment may be a metal-insulator-semiconductor (MIS) field effect transistor having a gate insulating film 141 between the gate electrode 106 and the electron supply layer 133, as shown in FIG. 6. The gate insulating film 141 may be a silicon oxide film, a silicon nitride film, etc. MIS transistors are advantageous in that a high sheet carrier concentration as well as high transconductance can be easily achieved as compared to HEMTs.

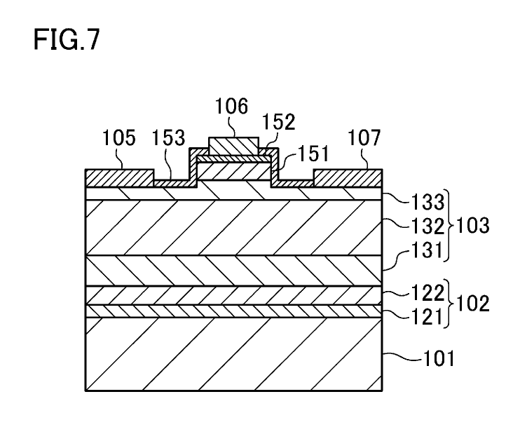

As shown in FIG. 7, a control layer 151 and a contact layer 152, each comprised of P-type GaN, may be provided between the gate electrode 106 and the electron supply layer 133. In this case, the gate electrode 106 forms ohmic junction with the P-type contact layer 152. The contact layer 152 may be any layer having a higher P-type impurity concentration than the control layer 151 so as to facilitate formation of the ohmic junction with the gate electrode 106.

The control layer 151 and the contact layer 152 can be formed by forming a P-type GaN layer and a highly doped P-type GaN layer over the electron supply layer 133, and then selectively dry etching the P-type GaN layer and the highly doped P-type GaN layer. In the case of using the dry etching process, it is preferable to form an insulating film 153 that covers the surface of the semiconductor layer.

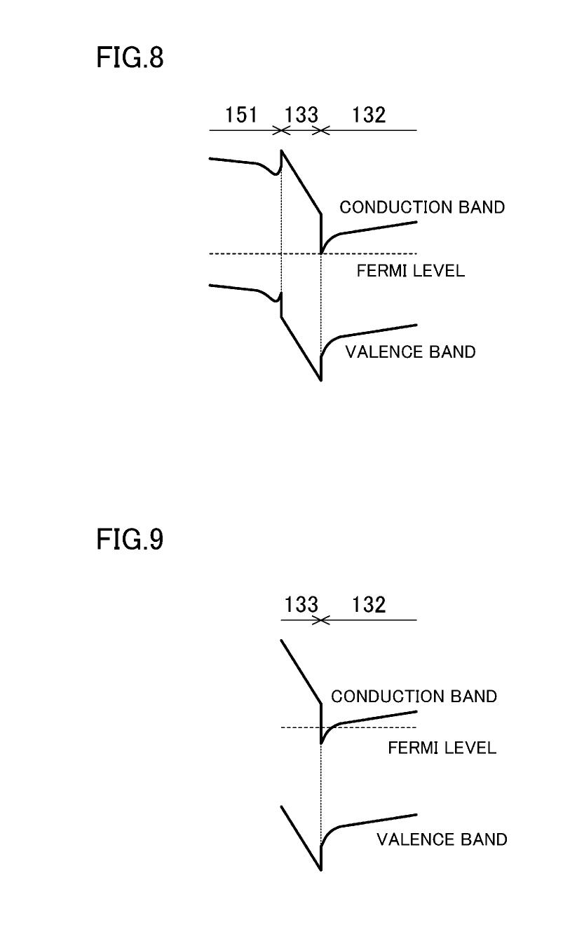

FIG. 8 shows an energy band of the electron transit layer 132, the electron supply layer 133, and the control layer 151 in the gate region. At the interface between the electron transit layer 132 and the electron supply layer 133, a valley is formed in the energy band due to charges generated by spontaneous polarization and piezoelectric polarization. However, the energy levels of the electron transit layer 132 and the electron supply layer 133 are raised since the control layer 151 is present in the gate region. Accordingly, the bottom of the valley in the conduction band which is formed at the interface between the electron transit layer 132 and the electron supply layer 133 is higher than the Fermi level. As a result, while no bias voltage is applied to the gate electrode, no 2DEG layer is formed in the gate region, and the transistor is in a normally off state. On the other hand, since there is no control layer 151 in a portion other than the gate region, a 2DEG layer is formed in this portion as shown in FIG. 9. Due to such characteristics, a large current can be made to flow between the source and the drain in the semiconductor device of FIG. 7 by applying a positive bias voltage to the gate electrode.

The nitride semiconductor device of the present embodiment has a high resistance at the interface between the silicon substrate and the buffer layer, and has a small amount of transmission loss. Accordingly, nitride semiconductor devices having a maximum operating frequency (fmax) of 2.5 GHz or more, and 25 GHz or more as shown in FIG. 5 can be easily implemented.

The present embodiment is described with respect to an example in which the nitride semiconductor layer is formed by an MOCVD method. However, any method can be used as long as a high quality nitride semiconductor layer can be formed. For example, a molecular beam epitaxy (MBE) method, a hydride vapor phase epitaxy (HYPE) method, etc. may be used instead of the MOCVD method.

The semiconductor device and the manufacturing method thereof according to the present disclosure can implement a semiconductor device having excellent high frequency characteristics, and are useful as a nitride semiconductor device formed on a silicon substrate, and a manufacturing method thereof, etc.

What is claimed is:

1. A nitride semiconductor device, comprising:
a silicon substrate;
a buffer layer formed on the silicon substrate and comprised of a nitride semiconductor; and
an active layer formed on the buffer layer and comprised of a nitride semiconductor, wherein
the buffer layer includes a first layer formed in contact with the silicon substrate, and a second layer formed in contact with the first layer and the active layer,
a carbon concentration at an interface between the first layer and the second layer is in a range of 1×10¹⁹ atoms/cm³ to 1×10²¹ atoms/cm³, both inclusive,
the first layer has a highest carbon concentration in a portion in contact with the silicon substrate, and
the second layer has a highest carbon concentration in a portion in contact with the first layer, and has a lowest carbon concentration in a portion in contact with the active layer.

2. The nitride semiconductor device of claim 1, wherein
each of the first layer and the second layer contains a group III element, and a composition of the group III element in the first layer is the same as that of the group III element in the second layer.

3. The nitride semiconductor device of claim 1, wherein
the second layer is thicker than the first layer.

4. The nitride semiconductor device of claim 1, wherein
the first layer has a thickness of 5 nm or more and less than 40 nm.

5. The nitride semiconductor device of claim 1, wherein
a full width at half maximum of a rocking curve of a (0001) plane of the second layer is 3,000 arc seconds or less.

6. The nitride semiconductor device of claim 1, wherein
a maximum operating frequency is 2.5 GHz or more.

7. The nitride semiconductor device of claim 1, wherein
a maximum operating frequency is 25 GHz or more.

8. A method for manufacturing a nitride semiconductor device, comprising the steps of:
(a) performing crystal growth of a first layer comprised of a nitride semiconductor on a silicon substrate;
(b) performing crystal growth of a second layer comprised of a nitride semiconductor on the first layer; and
(c) performing crystal growth of an active layer comprised of a nitride semiconductor on the second layer, wherein
the crystal growth is performed at a lower temperature in the step (a) than in the step (b).

9. A method for manufacturing a nitride semiconductor device, comprising the steps of:
(a) performing crystal growth of a first layer comprised of a nitride semiconductor on a silicon substrate;
(b) performing crystal growth of a second layer comprised of a nitride semiconductor on the first layer; and
(c) performing crystal growth of an active layer comprised of a nitride semiconductor on the second layer, wherein
a ratio of a group V element to a group III element contained in a source gas is lower in the step (a) than in the step (b).

10. A method for manufacturing a nitride semiconductor device, comprising the steps of:
(a) performing crystal growth of a first layer comprised of a nitride semiconductor on a silicon substrate;
(b) performing crystal growth of a second layer comprised of a nitride semiconductor on the first layer; and
(c) performing crystal growth of an active layer comprised of a nitride semiconductor on the second layer, wherein
in the step (a), a carbon material containing carbon is added to a source gas.

11. The method of claim 10, wherein
the carbon material is hydrocarbon.

12. The method of claim 10, wherein
the carbon material is carbon tetrabromide.
